(19) United States
(12) Patent Application Publication
(10) Pub. No.: US 2025/0051919 A1
(43) Pub. Date: Feb. 13, 2025

(54) SUBSTRATE PROCESSING APPARATUS AND SUBSTRATE PROCESSING METHOD

(71) Applicant: TES CO., LTD, Yongin-si (KR)

(72) Inventors: Shin-Myoung KIM, Yongin-si (KR); Hyun-Suk SONG, Yongin-si (KR); Hee-Won KIM, Yongin-si (KR)

(73) Assignee: TES CO., LTD, Yongin-si (KR)

(21) Appl. No.: 18/796,269

(22) Filed: Aug. 6, 2024

(30) Foreign Application Priority Data
Aug. 12, 2023 (KR) 10-2023-0105972

(51) Int. Cl. C23C 16/458; C23C 16/52

(52) U.S. Cl. CPC C23C 16/4583; C23C 16/52

(57) ABSTRACT

The present disclosure relates to a substrate processing apparatus and a substrate processing method, and more particularly, to a substrate processing apparatus and a substrate processing method for accurately accommodating a substrate at a central portion of a susceptor even when a tilt angle or a tilt direction of the susceptor on which the substrate is accommodated changes for each substrate or for each substrate process.

### CROSS-REFERENCE TO RELATED APPLICATION

This application is based on and claims priority under 35 U.S.C. § 119 to Korean Patent Application No. 10-2023-0105972, filed on Aug. 12, 2023, in the Korean Intellectual Property Office, the disclosure of which is incorporated by reference herein in its entirety.

### TECHNICAL FIELD

The present disclosure relates to a substrate processing apparatus and a substrate processing method, and more particularly, to a substrate processing apparatus and a substrate processing method for accurately accommodating a substrate at a central portion of a susceptor even when a tilt angle or a tilt direction of the susceptor on which the substrate is loaded changes for each substrate or for each substrate process.

### BACKGROUND

Generally, a substrate processing apparatus may include a chamber in which a process such as deposition and etching is to be performed on a substrate loaded in the chamber and include a heater or a susceptor to heat the substrate. A recessed portion into which the substrate is loaded may be formed on an upper surface of the susceptor.

In this configuration, when the substrate is loaded on the upper surface of the susceptor, more accurately, in the recessed portion of the susceptor, it is important that the substrate is placed at a central portion of the recessed portion. In other words, it is important that a distance between an edge of the substrate and the recessed portion is kept constant.

However, it is necessary to adjust a tilt angle and a tilt direction of the susceptor during processing for the substrate. This may be determined depending on process conditions for the substrate. For example, when processes are performed on a plurality of substrates, a predetermined tilt angle and tilt direction may vary for each substrate. When multiple processes are performed on one substrate, the tilt angle and the tilt direction may vary depending on each process condition.

As such, when the susceptor is tilted and the substrate is loaded in the recessed portion of the susceptor, the substrate may not be loaded in the central portion of the recessed portion but may be loaded biased to one side.

That is, the position of a central line in which the susceptor is tilted may be changed in the X-axis and Y-axis directions with respect to a central line in which the susceptor is horizontal. Therefore, when the substrate is loaded in line with the central line of the susceptor in a horizontal state, the substrate is located biased to one side in the recessed portion, and in a severe case, the substrate may not be loaded into the recessed portion and one side of the substrate covers an upper portion of the recessed portion.

In this case, a distance between an edge of the substrate and the recessed portion changes, causing a difference in a heat transfer rate between the substrate and the susceptor, and thus a deposition process on the substrate may not proceed smoothly, causing a thin film to be deposited unevenly on an upper surface of the substrate and causing arcing in processes using plasma.

### SUMMARY

To overcome the above problem, an object of the present disclosure is to provide a substrate processing apparatus and a substrate processing method for accurately accommodating a substrate at a central portion of a susceptor even when a tilt angle or a tilt direction of the susceptor on which the substrate is loaded changes for each substrate or for each substrate process.

According to an aspect of the present disclosure, a substrate processing apparatus includes a chamber providing a processing space for a substrate, a susceptor provided inside the chamber and configured to receive the substrate thereon and heat the substrate, a robot arm configured to load the substrate on the susceptor or unload the substrate from the susceptor, a tilt adjustment unit configured to adjust a tilt of the susceptor, and a controller configured to drive of the tilt adjustment unit and change a loaded position of the substrate on the susceptor by the robot arm, in accordance with the tilt of the susceptor.

A recessed portion into which the substrate is loaded may be formed on an upper surface of the susceptor, and the substrate may be located at a center of the recessed portion by the robot arm.

Tilt information of the susceptor corresponding to the substrate or tilt information of the susceptor corresponding to a process of the substrate and changed position information of the robot arm, corresponding to the tilt information of the susceptor, may be prestored as a tilt-changed position information table in the controller.

The tilt information of the susceptor may include at least one of a tilt angle or a tilt direction of the susceptor.

The controller may adjust at least one of a tilt angle or a tilt direction of the susceptor by driving the tilt adjustment unit based on tilt information of the susceptor corresponding to the substrate or tilt information of the susceptor corresponding to a process of the substrate, and change a loaded position of the substrate on the susceptor by the robot arm by extracting a changed position of the robot arm corresponding to the tilt angle and the tilt direction of the susceptor from the tilt-changed position information table.

The tilt adjustment unit may include a first adjustment unit that moves a support plate up and down a predetermined distance and a second adjustment unit that prevents the support plate from moving upward by negative pressure inside the chamber.

An extension extending downward from the susceptor may be connected to a lower elevating plate, the elevating plate may be provided to move up and down along a support bar, and the support bar may be fixed to the support plate connected to a lower portion of the chamber.

According to another aspect of the present disclosure, a substrate processing method of a substrate processing apparatus including a susceptor on which a substrate is loaded and a process is performed inside a chamber includes tilting at least one of a tilt angle or a tilt direction of the susceptor to a predetermined tilt angle and tilt direction, extracting a changed position of the robot arm from a tilt-changed position information table in accordance with the tilt angle and the tilt direction of the susceptor, and changing a position of the robot arm and accommodating the substrate on an upper surface of the susceptor.

Tilt information of the susceptor corresponding to the substrate or tilt information of the susceptor corresponding to a process of the substrate and changed position information of the robot arm corresponding to a tilt of the susceptor may be prestored as a tilt-changed position information table in a controller.

In the accommodating the substrate on the upper surface of the susceptor, a recessed portion into which the substrate is loaded may be provided on an upper surface of the susceptor, and the substrate may be loaded at a center of the recessed portion by the robot arm.

### BRIEF DESCRIPTION OF THE DRAWINGS

Embodiments will be more clearly understood from the following detailed description taken in conjunction with the accompanying drawings in which:

FIGS. 1 and 2 are side views of a substrate processing apparatus according to an embodiment of the present disclosure;

FIGS. 3A and 3B are a plan view and a side view of a susceptor of a substrate processing apparatus;

FIG. 4 is a perspective view of a tilt adjustment unit of a substrate processing apparatus;

FIG. 5 is a cross-sectional view taken along a line V-V of FIG. 4;

FIG. 6 is a graph showing a rotation angle of a rotation shaft of a tilt adjustment unit and an elevating distance of a support plate;

FIGS. 7A to 7C show a relationship between a rotation shaft and a rotation center of a cam member depending on a rotation angle of a rotation shaft of a tilt adjustment unit;

FIG. 8 is a graph showing a case in which a reference height is a height of a support plate when a phase of a rotation shaft is rotated 90°;

FIG. 9 is a plan of a support plate; and

FIGS. 10A to 11B are a plan view and a side view showing a state in which a susceptor is tilted.

### DETAILED DESCRIPTION OF THE EMBODIMENTS

Hereinafter, a substrate processing apparatus and a substrate processing method according to an embodiment of the present disclosure will be examined in detail with reference to the drawings.

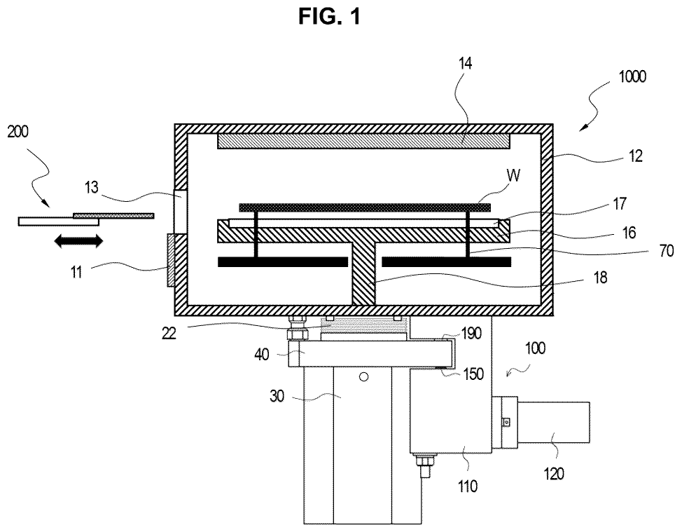

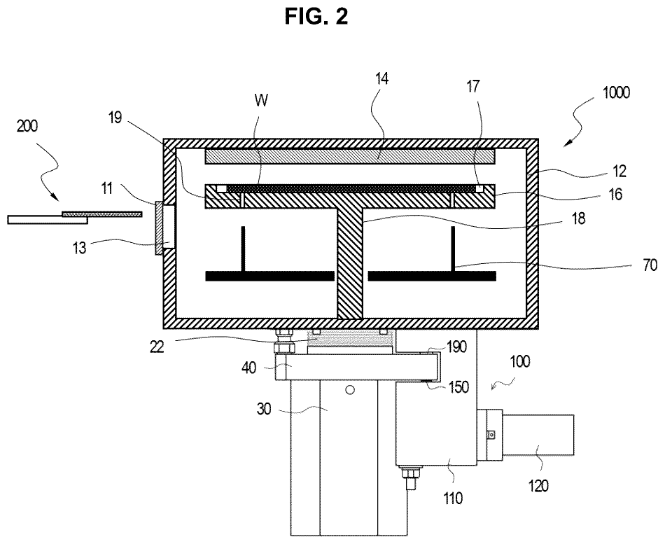

FIGS. 1 and 2 are side views of a substrate processing apparatus 1000 according to an embodiment of the present disclosure. FIG. 1 shows a state in which a susceptor 16 moves downward and a substrate W is loaded on a lift pin 70, and FIG. 2 shows a state in which the susceptor 16 moves upward to a process position and the substrate W is loaded on the susceptor 16.

Referring to FIGS. 1 and 2, the substrate processing apparatus 1000 may include a chamber 12 that provides a processing space for the substrate W.

An opening 13 may be formed at one side of the chamber 12, and the substrate W may be placed into the inside of the chamber 12 or taken out of the chamber 12 through the opening 13.

A door 11 may be provided in the opening 13, and the opening 13 may be sealed by driving the door 11. FIG. 1 shows a state in which the opening 13 is open, and FIG. 2 shows a state in which the opening 13 is blocked by the door 11. The configuration of the door 11 shown in FIGS. 1 and 2 is only an example, and may be implemented in various forms.

A robot arm 200 may be provided outside the chamber 12. The robot arm 200 may be capable of linear movement and vertical movement to enter the inside of the chamber 12 through the opening 13.

For example, the robot arm 200 may insert the substrate W into the chamber 12 and load the substrate W on the lift pin 70 inside the chamber 12, as shown in FIG. 1. When a process for the substrate W is completed, the susceptor 16 moves downward from the process position in FIG. 2 as shown in FIG. 1. In this case, the substrate W of the susceptor 16 is loaded on the lift pin 70, and the robot arm 200 extends and moves to a lower portion of the substrate W to unload the substrate.

A gas supply unit 14 that supplies a process gas toward the substrate W may be provided at an upper portion of the inside of the chamber 12. The gas supply unit 14 receives the process gas from a process gas source (not shown) located outside the chamber 12 and supplies the process gas toward the substrate W. The gas supply unit 14 may be configured as a so-called showerhead, but is not limited thereto.

The substrate W may be loaded inside the chamber 12, and the susceptor 16 heating the substrate W to a predetermined temperature may be provided. The susceptor 16 is provided to move up and down inside the chamber 12.

For example, an extension 18 extending downward from the susceptor 16 is connected to a lower elevating plate (not shown) through a bellows 22. The elevating plate is provided to move up and down along a support bar 30, and the support bar 30 is fixed to a support plate 40 connected to a lower portion of the chamber 12. In the present disclosure, provided is a tilt adjustment unit 100 that adjusts a tilt of the susceptor 16 by adjusting a tilt of the support plate 40, which will be described in detail later.

The susceptor 16 may include the lift pin 70 that moves the substrate W upward and downward. The lift pin 70 may be provided in a plural number, and the susceptor 16 may include a pinhole 19 through which the lift pin 70 passes.

As shown in FIG. 1, when the substrate W is introduced or the process for the substrate W is completed, the susceptor 16 moves downward. In this case, an upper end of the lift pin 70 protrudes through the pinhole 19. Therefore, the substrate W is loaded on the upper end of the lift pin 70 by the robot arm 200 described above, or the robot arm 200 may unload the substrate W located on the upper end of the lift pin 70.

As shown in FIG. 1, when the substrate W on which a process is not performed is loaded on the upper end of the lift pin 70, the opening 13 is sealed by the door 11 and the susceptor 16 moves upward to the process position as shown in FIG. 2. In this case, the lift pin 70 moves downward through the pinhole 19, and the substrate W is loaded on an upper surface of the susceptor 16.

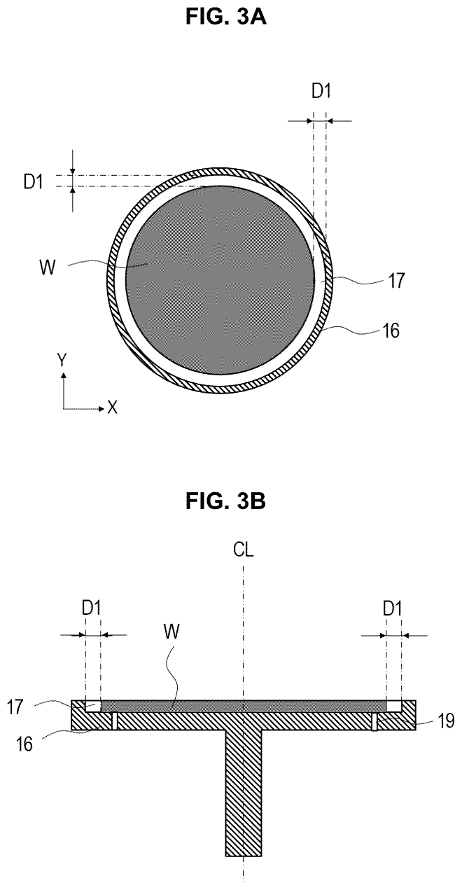

FIGS. 3A and 3B show a plan view and a side view of the susceptor 16 of the substrate processing apparatus 1000. FIG. 3A is a plan view of the susceptor 16, and FIG. 3B is a side view of the susceptor.

Referring to FIGS. 3A and 3B, an upper surface of the susceptor 16 may be provided with a recessed portion 17 into which the substrate W is loaded.

The recessed portion 17 may be formed to a predetermined depth. For example, the depth of the recessed portion 17 may correspond to a thickness of the substrate W, but is not limited thereto and may be appropriately modified.

When the substrate W is loaded on the upper surface of the susceptor 16, more accurately, in the recessed portion 17 of the susceptor 16, it is important to locate the substrate W at the central portion of the recessed portion 17. That is, as shown in FIGS. 3A and 3B, it is important that a distance D1 between an edge of the substrate W and the recessed portion 17 is maintained constant.

When the distance D1 between the edge of the substrate W and the recessed portion 17 is not constant, a distance between the substrate W and the recessed portion 17 varies. Accordingly, a difference occurs in a heat transfer rate between the substrate W and the susceptor 16, and thus the process for the substrate W, such as a deposition process, may not proceed smoothly, and a thin film may be formed unevenly on the upper surface of the substrate W. Arcing may occur in processes using plasma.

In this case, the above-described robot arm 200 moves in the X-axis and Y-axis directions on the upper portion of the susceptor 16 and accommodates the substrate W on the above-described lift pin 70 corresponding to a predetermined central line CL of the susceptor 16 or the recessed portion 17. The substrate W loaded on the lift pin 70 is loaded at the central portion of the recessed portion 17 as described in FIG. 2.

It is necessary to adjust a tilt angle and a tilt direction of the susceptor 16 during processes for the substrate W. This may be determined depending on process conditions for the substrate W. For example, when processes are performed on a plurality of substrates W, a predetermined tilt angle and tilt direction may vary for each substrate W. When multiple processes are performed on one substrate W, the tilt angle and the tilt direction may vary depending on each process condition.

In the present disclosure, to change the tilt angle and the tilt direction of the susceptor 16, the tilt adjustment unit 100 may be driven as described above. The tilt adjustment unit 100 adjusts the tilt angle and the tilt direction of the susceptor 16 by changing the tilt angle and the tilt direction of the support plate 40 described above.

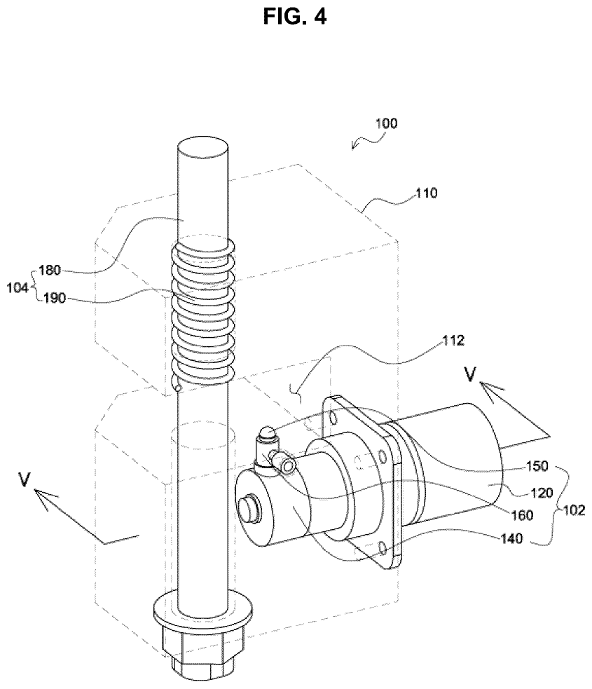

FIG. 4 is a perspective view of the tilt adjustment unit 100 of the substrate processing apparatus 1000.

Referring to FIGS. 1 and 4, the tilt adjustment unit 100 may include a first adjustment unit 102 that moves the support plate 40 up and down a predetermined distance and a second adjustment unit 104 that prevents the support plate 40 from moving upward by negative pressure inside the chamber 12.

That is, the first adjustment unit 102 moves one side of the support plate 40 up and down to adjust a tilt of the support plate 40, as will be described later.

However, the support plate 40 is connected to the susceptor 16 through the support bar 30, and the susceptor 16 is located inside the chamber 12. In this case, when the inside of the chamber 12 is maintained in a predetermined vacuum state for a deposition process, and the like, negative pressure is applied inside the chamber 12, and the susceptor 16 moves upward by the negative pressure. The upward movement changes a distance between the susceptor 16 and the gas supply unit 14 inside the chamber 12.

Therefore, when negative pressure is applied inside the chamber 12, the second adjustment unit 104 prevents the support plate 40 from moving upward, and thus the susceptor 16 connected to the support plate 40 may be prevented from moving upward to maintain a distance between the susceptor 16 and the gas supply unit 14.

The first adjustment unit 102 is provided in a housing 110 connected to a lower portion of the chamber 12, as shown in FIGS. 1 and 4. The housing 110 is fixed to a lower portion of the chamber 12 and includes a groove 112 formed therein into which one side of the support plate 40 is inserted. With one side of the support plate 40 inserted into the groove 112, one side of the support plate 40 is slightly moved up and down by the above-described first adjustment unit 102 or the support plate 40 is prevented from moving upward to fix the height of the support plate 40 by the second adjustment unit 104.

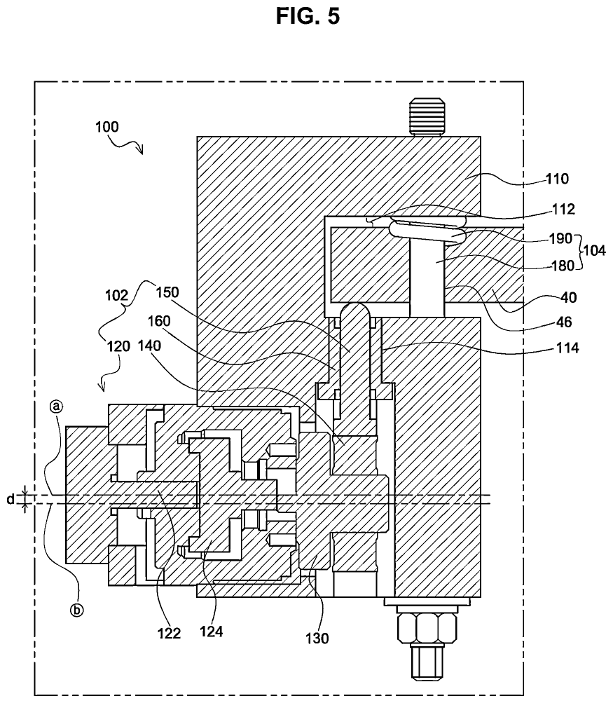

FIG. 5 is a cross-sectional view taken along a line V-V of FIG. 4.

Referring to FIG. 5, the first adjustment unit 102 includes a cam member 130 that applies a predetermined force to the support plate 40 and a driver 120 that is spaced a predetermined distance from a rotation center of the cam member 130 and is connected to the cam member 130 to rotate the cam member 130.

The driver 120 such as a motor is provided in the housing 110, and a rotation shaft 122 extending from the driver 120 is connected to the cam member 130. In this case, the cam member 130 and the driver 120 may be connected to each other such that the rotation center of the cam member 130 and the rotation shaft 122 of the driver 120 are spaced apart from each other by a predetermined distance d. In FIG. 5, line (a) corresponds to an imaginary line extending from the center of the rotation shaft 122 of the driver 120, and line (b) corresponds to an imaginary line extending from the center of the rotation center of the cam member 130.

That is, the rotation shaft 122 of the driver 120 is not connected to the rotation center of the cam member 130, but the rotation shaft 122 of the driver 120 is connected to a point spaced a predetermined distance away from the rotation center of the cam member 130. In the above structure, when the rotation shaft 122 is rotated by driving of the driver 120, the cam member 130 also rotates in conjunction with the rotation shaft 122.

In this case, the rotation center of the cam member 130 is located spaced apart from the center of the rotation shaft 122, and thus when the cam member 130 rotates, a distance between an outer circumference of the cam member 130 and the rotation shaft 122 changes. That is, when the cam member 130 rotates, the outer circumference of the cam member 130 does not form a constant circular trajectory, but forms an irregular trajectory in which the distance from the rotation shaft 122 changes. Therefore, when the distance between the outer circumference of the cam member 130 and the rotation shaft 122 increases relatively, the support plate 40 may move upward, and in contrast, when the outer circumference of the cam member 130 and the rotation shaft 122 reduces relatively, the support plate 40 may move downward.

In this case, further provided may be a bearing portion 140 that is located between the cam member 130 and the support plate 40, surrounds the outer circumference of the cam member 130, and applies a predetermined force to the support plate 40. The bearing portion 140 prevents the cam member 130 from directly contacting a push bar 150, which will be described later, and prevents wear of the cam member 130 or the push bar 150.

The tilt adjustment unit 100 may further include is the push bar 150, one end of which is in contact with the outer circumference of the bearing portion 140 to apply a predetermined force to the support plate 40 by rotation of the bearing portion 140.

The push bar 150 is provided to move up and down through a linear bush 160 that is provided to pass through an opening 114 provided on the other side of the housing 110. When the push bar 150 moves up and down by rotation of the cam member 130, the linear bush 160 guides the up and down movement of the push bar 150. Therefore, when the bearing portion 140 rotates together with rotation of the cam member 130, the push bar 150 moves up and down to move the support plate 40 upward and downward.

The push bar 150 supports the support plate 40 and prevents the support plate 40 from sagging. That is, when the cam member 130 does not rotate, the cam member 130 is engaged and fixed with the rotation shaft 122, and thus the height of the upper end of the push bar 150 may be fixed to support the support plate 40 and to prevent the support plate 40 from sagging.

A reducer 124 may be located between the cam member 130 and the rotation shaft 122. The reducer 124 reduces a rotational force of the rotation shaft 122 and transmits the rotational force it to the cam member 130. In this case, a deceleration ratio of the reducer 124 may be determined in accordance with the maximum distance over which the support plate 40 is to move upward and downward.

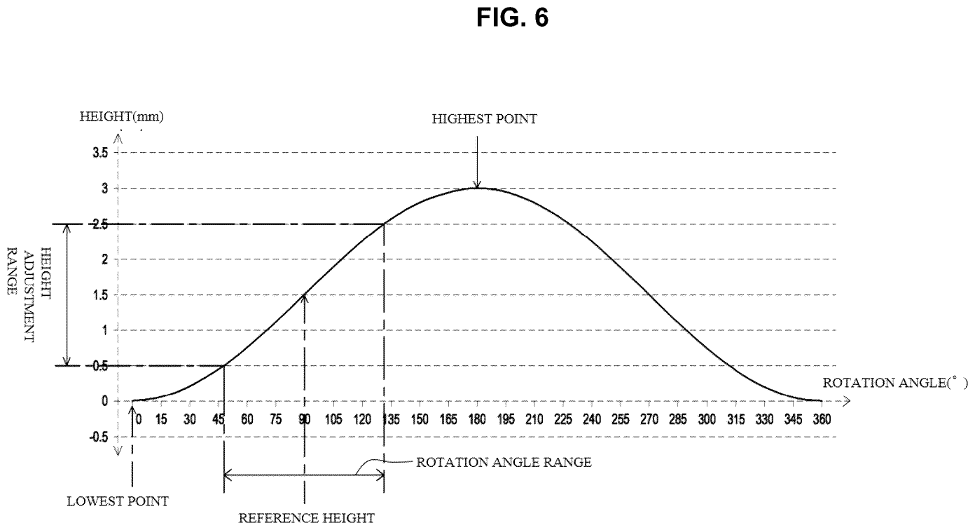

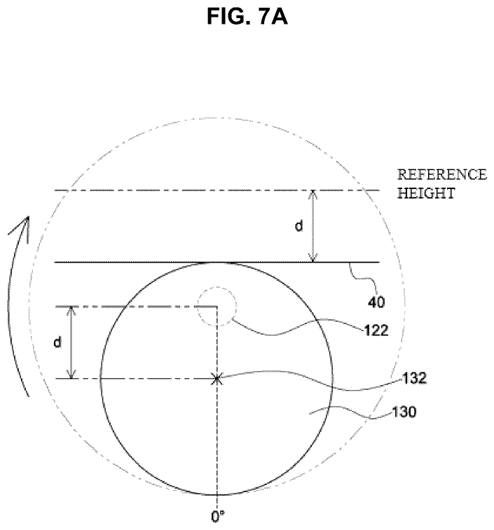

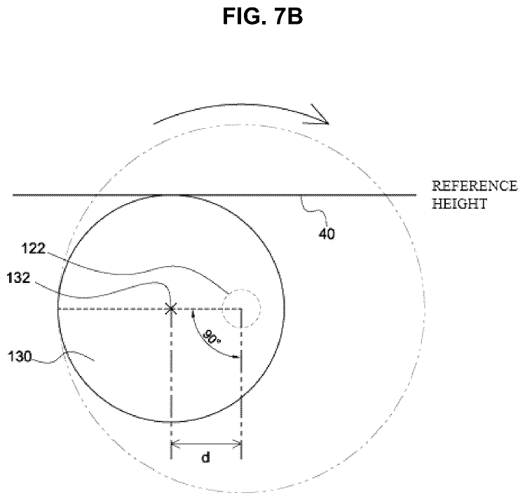

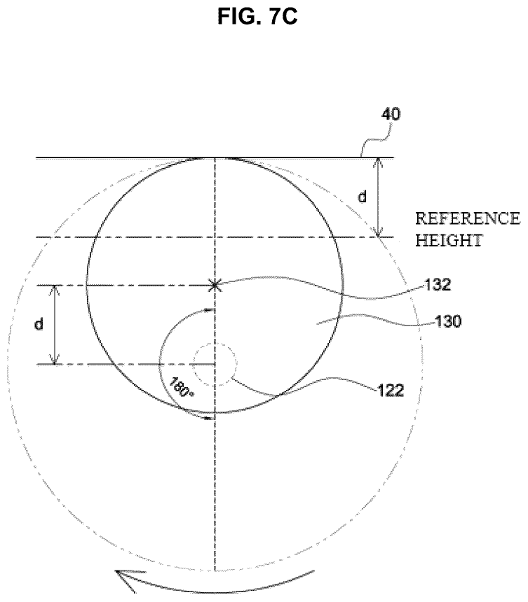

FIG. 6 shows a rotation angle of the rotation shaft 122 of the driver 120 provided in the first adjustment unit 102 of the tilt adjustment unit 100 and an elevation distance of the support plate 40, and FIGS. 7A to 7C show a relationship between the rotation shaft 122 and a rotation center 132 of the cam member 130 depending on a rotation angle of the rotation shaft 122.

In FIG. 6, the horizontal axis represents a rotation angle) (° of the rotation shaft 122, and the vertical axis represents an elevating distance (mm) of the support plate 40. FIG. 7A shows a case in which a phase of the rotation shaft 122 rotates 0° clockwise, FIG. 7B shows a case in which the phase of the rotation shaft 122 rotates 90° clockwise, and FIG. 7C shows a case in which phase of the rotation shaft 122 rotates 180° clockwise. In FIGS. 7A to 7C, for convenience, it is assumed that the rotation shaft 122 rotates clockwise, but the rotation shaft 122 may rotate in an opposite direction.

Referring to FIGS. 6 to 7C, a tilt adjusting method includes setting a height of the support plate 40 to a reference height when the rotation shaft 122 and the rotation center of the cam member 130 are horizontal to each other by rotating the rotation shaft 122, setting a range of a rotation angle of the rotation shaft 122 to be less than 180° when the rotation shaft 122 rotates in a forward or reverse direction from the reference height, and moving the support plate 40 upward and downward by rotating the rotation shaft 122 in either the forward or reverse direction.

First, the height of the support plate 40 when the rotation shaft 122 and the rotation center of the cam member 130 are horizontal to each other due to rotation of the rotation shaft 122 may be set to the reference height. In FIG. 7B, the rotation shaft 122 and the rotation center 132 of the cam member 130 are in a horizontal state, and in this case, the height of the support plate 40 by the cam member 130 is set to the reference height.

In FIG. 7A, the rotation shaft 122 and the rotation center 132 of the cam member 130 are arranged perpendicularly to each other, and the rotation center 132 is located below the rotation shaft 122. In this case, the outer circumference of the cam member 130 in contact with the support plate 40 is located below the reference height, and in this case, the support plate 40 is located below the reference height. In this case, a distance between the support plate 40 and the reference height is equal to a separation distance d between the rotation shaft 122 and the rotation center.

In this state, when the rotation shaft 122 further rotates 90° clockwise to reach the state shown in FIG. 7B, the rotation shaft 122 and the rotation center 132 are arranged horizontally to each other, and the rotation center 132 and the rotation shaft 122 are located at the same height. In this case, the outer circumference of the cam member 130 in contact with the support plate 40 corresponds to the reference height, and the support plate 40 is located at the reference height.

In this state, when the rotation shaft 122 further rotates 90° clockwise to reach the state shown in FIG. 7C, the rotation shaft 122 and the rotation center 132 are arranged perpendicularly to each other, and the rotation center 132 is located above the rotation shaft 122. In this case, the outer circumference of the cam member 130 in contact with the support plate 40 exceeds the reference height and moves the support plate 40 upward. In this case, a distance between the support plate 40 and the reference height is equal to a separation distance d between the rotation shaft 122 and the rotation center 132.

As described above, the reason for setting the height of the support plate 40 when the rotation shaft 122 and the rotation center of the cam member 130 are horizontal to each other due to rotation of the rotation shaft 122 (when a phase of the rotation shaft is located at 90° or 270° in FIG. 6) to the reference height is to place a height adjustment range of the support plate 40 by rotation of the rotation shaft 122 between the highest point and lowest point of the support plate 40 when the support plate 40 is moved up and down.

That is, when the rotation shaft 122 rotates in forward or reverse directions at the reference height, if a range of the rotation angle of the rotation shaft 122 is set to be less than 180°, or if the height adjustment range of the support plate 40 due to rotation of the rotation shaft 122 is set to be less than twice a separation distance between the rotation shaft 122 and a rotation center 142 of the cam member 130, the height adjustment range of the support plate 40 is located between the highest point and lowest point of the support plate 40, as shown in FIG. 6.

For example, in FIG. 6, when the separation distance between the rotation shaft 122 and the rotation center 142 of the cam member 130 corresponds to 1.5 mm, the distance between the highest point and lowest point of the support plate 40 corresponds to twice the separation distance, and the height adjustment range is set to 2.0 mm, and a margin of 0.5 mm may be provided on both sides of the height adjustment range up to the highest point and the lowest point.

However, when the reference height is set, it is realistically difficult to accurately set the height of the support plate 40 when the rotation shaft 122 and the rotation center of the cam member 130 are horizontal to each other (when the phase of the rotation shaft is located at 90° or 270° in FIG. 6) to the reference height.

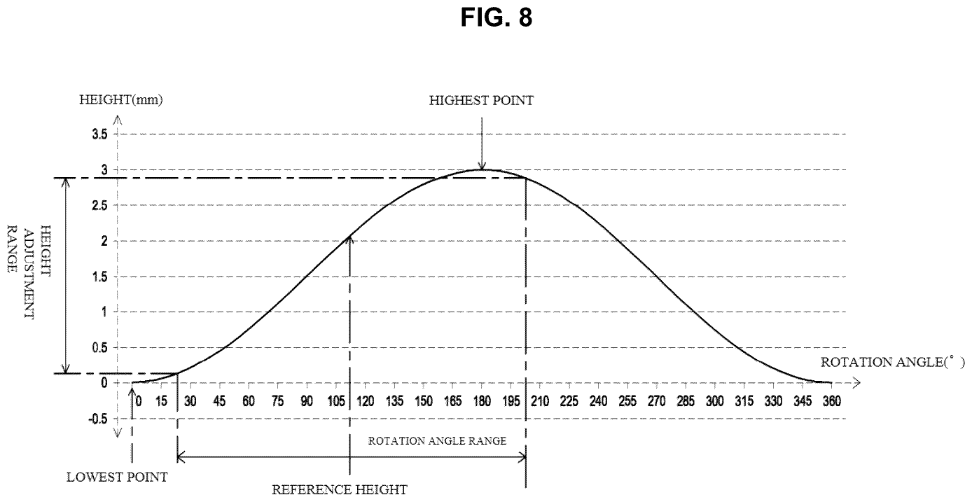

Therefore, as shown in FIG. 8, when the height of the support plate 40 in the case in which the phase of the rotation shaft 122 deviates from 90° is set to the reference height and a range of the rotation angle of the rotation shaft 122 is set to 180°, the height adjustment range of the support plate 40 deviates from a range between the height point and lowest point of the support plate 40.

That is, when the rotation shaft 122 is rotated to move the support plate 40 upward as much as possible, the range of the rotation angle of the rotation shaft 122 exceeds 180° at which the support plate 40 reaches the highest point. In this case, even if the phase of the rotation shaft 122 is rotated to more than 180°, the support plate 40 no longer moves upward, but rather moves downward from a moment when the phase of the rotation shaft 122 exceeds 180°. Therefore, when the tilt of the support plate 40 is adjusted by adjusting the height of the support plate 40 by driving control of the rotation shaft 122, the tilt adjustment may not be properly performed.

In the end, after setting a rotation angle range of the rotation shaft 122 or the height adjustment range of the support plate 40 as described above, the rotation shaft 122 is rotated in either the forward or reverse direction to move the support plate 40 upward and downward.

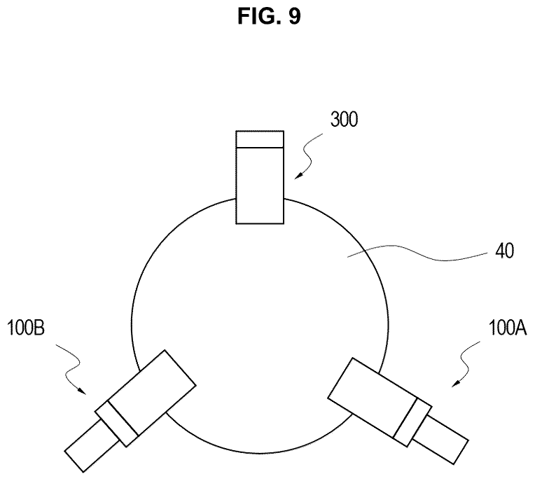

FIG. 9 is a plan view of the support plate 40, showing the support plate 40 and tilt adjustment units 100A and 100B.

As described above, to adjust the tilt angle and the tilt direction of the support plate 40 by the tilt adjustment units 100A and 100B, a plurality of tilt adjustment units 100A and 100B rather than one may be provided.

For example, as shown in FIG. 9, two tilt adjustment units 100A and 100B may be provided on the support plate 40. Here, the number of tilt adjustment units 100A and 100B is explained as an example, and it may be possible to have more than two.

In this case, the support plate 40 may be supported by the plurality of tilt adjustment units 100A and 100B, or may be supported by a fixing unit 300 and the plurality of tilt adjustment units 100A and 100B. Hereinafter, it is assumed that one fixing unit 300 and two tilt adjustment units 100A and 100B are provided.

Here, the fixing unit 300 may not adjust the tilt angle of the support plate 40 and may simply fix and support the support plate 40.

The configuration of the tilt adjustment units 100A and 100B has already been described in detail, and thus repetitive description will be omitted.

As shown in FIG. 9, when one fixing unit 300 and two tilt adjustment units 100A and 100B are provided, the fixing unit 300 and the tilt adjustment units 100A and 100B may be arranged symmetrically. For example, the fixing unit 300 and the tilt adjustment units 100A and 100B may each be arranged at a central angle of 120 degrees with respect to the central portion of the support plate 40.

When the fixing unit 300 is provided as described above, the fixing unit 300 may be connected to the support plate 40 in a direction toward the opening 13 of the chamber 12.

As such, when the plurality of tilt adjustment units 100A and 100B are provided, the tilt angles of the tilt adjustment units 100A and 100B of the tilt adjustment unit 100 may be the same or different from each other.

The tilt angles and the tilt directions of the support plate 40 and the susceptor 16 may be adjusted by setting the tilt angles of the tilt adjustment units 100A and 100B to be the same or different from each other.

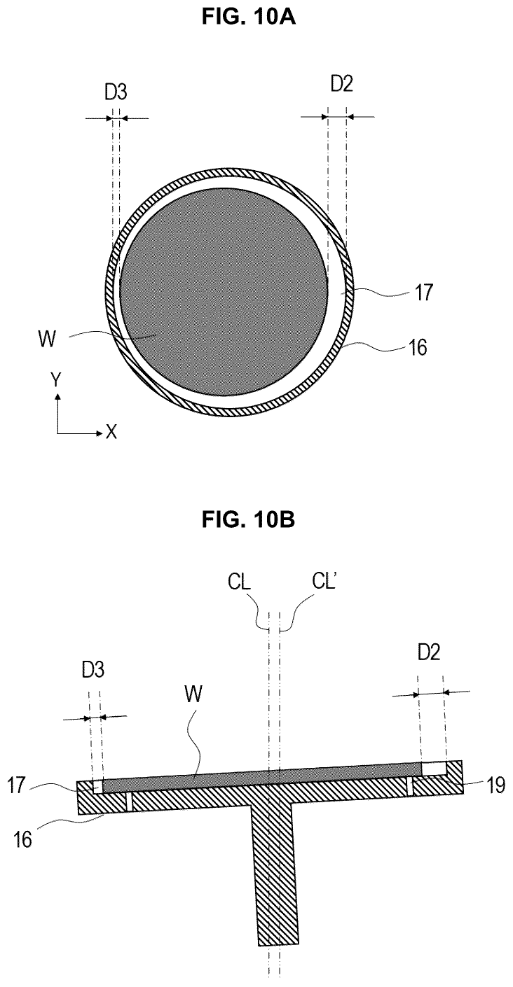

FIGS. 10A and 10B are a plan view and a side view of the susceptor 16 in a tilted state. FIGS. 10A and 10B show a state in which the substrate W is loaded on the susceptor 16 tilted according to the related art.

Referring to FIGS. 10A and 10B, when the susceptor 16 is tilted and the substrate W is loaded in the recessed portion 17 of the susceptor 16 by the robot arm 200, the substrate W may not be loaded at the central portion of the recessed portion 17 but may be loaded biased to one side.

That is, when the susceptor 16 is tilted, the position of a second central line CL′ in a state in which the susceptor 16 is tilted with respect to a first central line CL in a state in which the susceptor 16 is horizontal may be changed in X-axis and Y-axe directions. Therefore, when the robot arm 200 accommodates the substrate W on the above-described lift pin 70 in line with the first central line CL in a state in which the susceptor 16 is horizontal, the substrate W is located biased to one side of the recessed portion 17, as shown in FIGS. 10A and 10B, and in a severe case, the substrate W is loaded in the recessed portion 17 and one side of the substrate W covers an upper portion of the recessed portion 17.

In this case, distances D2 and D3 between the edge of the substrate W and the recessed portion 17 change, causing a difference in heat transfer rate between the substrate W and the susceptor 16, and thus the process for the substrate W may not proceed smoothly, and arcing may occur in processes using plasma.

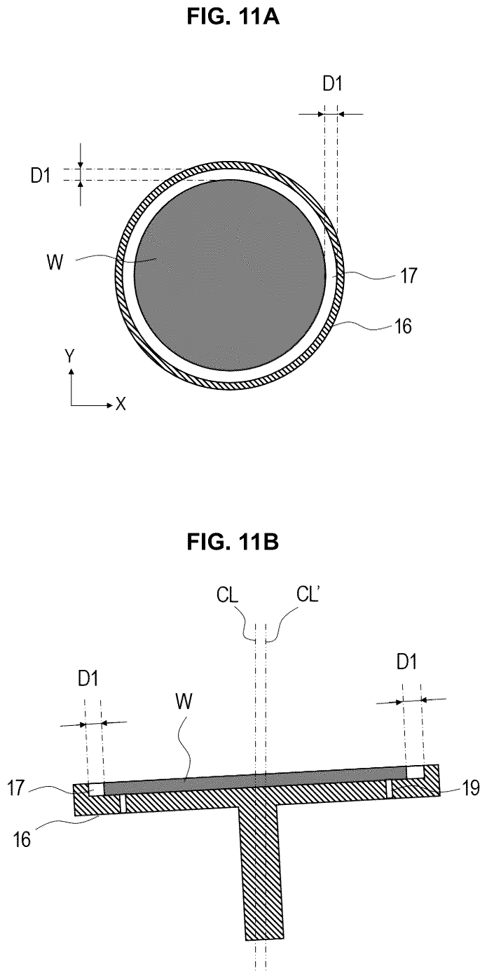

FIGS. 11A and 11B are a plan view and a side view of the susceptor 16 in a tilted state. FIGS. 11A and 11B show a state in which the substrate W is loaded on the susceptor 16 tilted according to the present disclosure.

Referring to FIGS. 11A and 11B, the substrate processing apparatus 1000 may include a controller (not shown) that drives of the tilt adjustment unit 100 and changes a loaded position of the substrate W on the susceptor 16 by the robot arm 200, in accordance with a tilt of the susceptor 16.

For example, tilt information of the susceptor 16 corresponding to the substrate W or tilt information of the susceptor 16 corresponding to a process of the substrate W and changed position information of the robot arm 200 corresponding to the tilt information of the susceptor 16 may be prestored as a tilt-changed position information table in the controller.

That is, tilt information of the susceptor 16 corresponding to the substrate W or tilt information of the susceptor 16 corresponding to a process of the substrate W and an X-axis and Y-axis changed position of the robot arm 200 corresponding to the tilt information of the susceptor 16 may be organized in table form.

Here, the tilt information of the susceptor 16 may include at least one of the tilt angle or the tilt direction of the susceptor 16. Thus, the tilt information of the susceptor 16 may include only one of the tilt angle or the tilt direction of the susceptor 16 or both.

For example, when the plurality of tilt adjustment units 100 are provided as described above, a driving time, a driving voltage, or a driving speed for driving the driver 120 of each tilt adjustment unit 100 may be predetermined for each substrate or for each substrate process. A change in height of the susceptor 16 may be directly determined by driving each tilt adjustment unit 100.

The driving time, driving voltage, or driving speed for driving the driver 120 of each tilt adjustment unit 100 described above may be input as an input condition to the tilt-changed position information table described above. A change in height of the susceptor 16 corresponding to driving of each tilt adjustment unit 100 may be directly input as an input condition to the tilt-changed position information table described above.

In accordance with the input condition, the changed position information of the robot arm 200 may be input as X-axis correction coordinates and Y-axis correction coordinates.

Therefore, a method of processing a substrate by using the substrate processing apparatus 1000 includes tilting at least one of a tilt angle or a tilt direction of the susceptor 16 in a predetermined tilt angle and tilt direction, extracting a changed position of the robot arm 200 from the tilt-changed position information table in accordance with the tilt angle and the tilt direction, and changing the position of the robot arm 200 to accommodate the substrate W on an upper surface of the susceptor 16.

First, the controller may adjust the tilt angle and the tilt direction of the susceptor 16 by driving of the driver 120 of each tilt adjustment unit 100 based on the tilt information of the susceptor 16 corresponding to substrate W or the tilt information of the susceptor 16 corresponding to the process of the substrate W.

In this case, when the plurality of tilt adjustment units 100 are provided, a driving time, a driving voltage, or a driving speed for driving the driver 120 of each tilt adjustment unit 100 may be adjusted for each substrate or for each substrate process. The height of the susceptor 16 may be directly adjusted by driving each tilt adjustment unit 100.

Then, the controller may extract the changed position of the robot arm 200 corresponding to the tilt angle and the tilt direction of the susceptor 16 from the tilt-changed position information table.

In this case, the controller may extract the X-axis correction coordinates and Y-axis correction coordinates of the robot arm 200 corresponding to a driving time, driving voltage, or driving speed for driving the driver 120 of each tilt adjustment unit 100, and the height of the susceptor 16 from the tilt-changed position information table.

Then, the controller changes the position of the robot arm 200 corresponding to the X-axis correction coordinates and Y-axis correction coordinates of the robot arm 200 and accommodates the substrate W on the upper surface of the susceptor 16.

When the above-described process is performed, even if the susceptor 16 is tilted at a predetermined angle and direction, the substrate W may be loaded in accordance with a new second central line CL′ of the recessed portion 17 as described with reference to FIGS. 11A and 11B, and thus a distance D1 between the edge of the substrate W and the recessed portion 17 may be maintained constant.

As a result, the process for the substrate W may proceed smoothly, for example, a thin film may be uniformly deposited on the upper surface of the substrate W, and arcing may be prevented in processes using plasma.

According to the present disclosure having the above-described configuration, even when the tilt angle or the tilt direction of the susceptor on which the substrate is mounted changes for each substrate or each substrate process, the changed position information of the robot arm corresponding to the tilt information of the susceptor may be extracted from the tilt-changed position information table, and the substrate may be accurately loaded at the central portion of the susceptor.

Although the present disclosure has been described above with reference to exemplary embodiments, those skilled in the art may modify and change the present disclosure in various ways without departing from the spirit and scope of the present disclosure as set forth in the claims described below. Therefore, when the modified implementation basically includes the elements of the claims of the present disclosure, it should be considered to be included in the technical scope of the present disclosure.

What is claimed is:

1. A substrate processing apparatus comprising:
a chamber providing a processing space for a substrate;
a susceptor provided inside the chamber and configured to receive the substrate thereon and heat the substrate;
a robot arm configured to load the substrate on the susceptor or unload the substrate from the susceptor;
a tilt adjustment unit configured to adjust a tilt of the susceptor; and
a controller configured to drive the tilt adjustment unit and change a loaded position of the substrate on the susceptor by the robot arm, in accordance with the tilt of the susceptor.

2. The substrate processing apparatus of claim 1, wherein a recessed portion into which the substrate is loaded is formed on an upper surface of the susceptor, and
the substrate is loaded at a center of the recessed portion by the robot arm.

3. The substrate processing apparatus of claim 1, wherein tilt information of the susceptor corresponding to the substrate or tilt information of the susceptor corresponding to a process of the substrate and changed position information of the robot arm, corresponding to the tilt information of the susceptor, are prestored as a tilt-changed position information table in the controller.

4. The substrate processing apparatus of claim 3, wherein the tilt information of the susceptor includes at least one of a tilt angle or a tilt direction of the susceptor.

5. The substrate processing apparatus of claim 1, wherein the controller adjusts at least one of a tilt angle or a tilt direction of the susceptor by driving the tilt adjustment unit based on tilt information of the susceptor corresponding to the substrate or tilt information of the susceptor corresponding to a process of the substrate, and changes a loaded position of the substrate on the susceptor by the robot arm by extracting a changed position of the robot arm corresponding to the tilt angle and the tilt direction of the susceptor from the tilt-changed position information table.

6. The substrate processing apparatus of claim 1, wherein the tilt adjustment unit includes a first adjustment unit that moves a support plate up and down a predetermined distance and a second adjustment unit that prevents the support plate from moving upward by negative pressure inside the chamber.

7. The substrate processing apparatus of claim 6, an extension extending downward from the susceptor is connected to a lower elevating plate, the elevating plate is provided to move up and down along a support bar, and the support bar is fixed to the support plate connected to a lower portion of the chamber.

8. A substrate processing method of a substrate processing apparatus including a susceptor on which a substrate is loaded and a process is performed inside a chamber, the method comprising:
tilting at least one of a tilt angle or a tilt direction of the susceptor to a predetermined tilt angle and tilt direction;
extracting a changed position of the robot arm from a tilt-changed position information table in accordance with the tilt angle and the tilt direction of the susceptor; and
changing a position of the robot arm and loading the substrate on an upper surface of the susceptor.

9. The method of claim 8, wherein tilt information of the susceptor corresponding to the substrate or tilt information of the susceptor corresponding to a process of the substrate and changed position information of the robot arm corresponding to a tilt of the susceptor are prestored as a tilt-changed position information table in a controller.

10. The method of claim 8, wherein, in the loading the substrate on the upper surface of the susceptor, a recessed portion into which the substrate is loaded is provided on an upper surface of the susceptor, and the substrate is loaded at a center of the recessed portion by the robot arm.
